(19) United States
(12) Patent Application Publication
(10) Pub. No.: US 2007/0080352 A1
(43) Pub. Date: Apr. 12, 2007

(54) LIGHT-EMITTING DIODE CHIP

(76) Inventors: Liang-Wen Wu, Tao-Yung Hsien (TW); Ming-Sheng Chen, Tao-Yung Hsien (TW); Ya-Ping Tsai, Tao-Yung Hsien (TW); Fen-Ren Chien, Tao-Yung Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/307,042

(22) Filed: Jan. 20, 2006

(30) Foreign Application Priority Data
Oct. 7, 2005 (TW) 94135122

(51) Int. Cl. H01L 33/00

(52) U.S. Cl. 257/79

(57) ABSTRACT

A LED chip includes a substrate, a semiconductor layer, a micro-rough layer, a first electrode and a second electrode. The semiconductor layer is disposed on the substrate, the micro-rough layer is disposed in the semiconductor layer, or between the semiconductor layer and the substrate, or on an upper surface of the semiconductor layer. Both the first electrode and the second electrode are disposed on the semiconductor layer. The first electrode is electrically insulated from the second electrode. In this way, the above-described LED chip has better luminous efficiency.

### CROSS-REFERENCE TO RELATED APPLICATION

This application claims the priority benefit of Taiwan application serial no. 94135122, filed on Oct. 7, 2005. All disclosure of the Taiwan application is incorporated herein by reference.

### BACKGROUND OF THE INVENTION

1. Field of Invention

The present invention relates to a light-emitting diode (LED) chip, and particularly to LED chip having high luminous efficiency.

2. Description of the Related Art

LED chips are a kind of semiconductor device fabricated by chemical elements of group III-V, such as gallium phosphide (GaP), gallium arsenide (GaAs) and gallium nitride (GaN). By applying current to the compound semiconductors, and through the recombination of electrons and holes, the electric energy is converted into light energy and released in photon form to achieve light radiation. The radiation of a LED is of a cold mechanism, but not through heat, therefore the lifetime of LEDs can be over a hundred thousand hours and no idling time is required. In addition, LEDs have such advantages as fast response speed (about 10⁻⁹ second), small volume, low power consumption, low pollution (no mercury), high reliability and adaptation to mass production. Hence, LEDs have wide applications, such as light sources of scanners, backlight of liquid crystal displays, outdoor display boards, or vehicle lightings.

The luminous efficiency of a LED chip mainly depends on the internal quantum efficiency and external quantum efficiency thereof. The internal quantum efficiency is determined by the probability of releasing photons after electrons and holes are recombined. The easier the electrons are recombined with holes, the higher the internal quantum efficiency is. The external quantum efficiency is determined by the probability of photon escaping from the LED. The more photons released outside, the higher the external quantum efficiency is.

A conventional LED chip mainly includes a plurality of thin film layers made of different materials, such as P-type semiconductor layer, N-type semiconductor layer and light-emitting layer. To escape from a LED, photons need to successfully pass through the thin films. Therefore, the external quantum efficiency mainly depends on the forms and refractive indexes of thin films. If, for example, a refractive index difference between any two adjacent thin films is excessive, the photons may be consumed inside the LED chip due to a total reflection, which limits the external quantum efficiency and lowers the LED luminous efficiency.

### SUMMARY OF THE INVENTION

The present invention is directed to provide a LED chip having at least a micro-rough layer and higher luminous efficiency.

As embodied and broadly described herein, the present invention provides a LED chip including a substrate, a semiconductor layer, a micro-rough layer, a first electrode and a second electrode. The semiconductor layer is disposed on the substrate, while the micro-rough layer is disposed in the semiconductor layer. The first electrode and the second electrode are disposed on the semiconductor layer, wherein the first electrode is electrically insulated from the second electrode.

In an embodiment of the present invention, the semiconductor layer includes a first-type doped semiconductor layer, a light-emitting layer and a second-type doped semiconductor layer. The first-type doped semiconductor layer is disposed on the substrate, the light-emitting layer is disposed on a portion of the first-type doped semiconductor layer, while the second-type doped semiconductor layer is disposed on the light-emitting layer. The first electrode is electrically connected to the first-type doped semiconductor layer, while the second electrode is electrically connected to the second-type doped semiconductor layer.

In an embodiment of the present invention, the micro-rough layer is disposed, for example, in the first-type doped semiconductor layer, or between the first-type doped semiconductor layer and the light-emitting layer, or in the light-emitting layer, or between the light-emitting layer and the second-type doped semiconductor layer, or in the second-type doped semiconductor layer.

In an embodiment of the present invention, the first-type doped semiconductor layer is, for example, a N-type doped semiconductor layer, while the second-type doped semiconductor layer is, for example, a P-type doped semiconductor layer.

In an embodiment of the present invention, the first-type doped semiconductor layer includes a buffer layer, a first contact layer and a first cladding layer. The buffer layer is disposed on the substrate, the first contact layer is disposed on the buffer layer, while the first cladding layer is disposed on the first contact layer.

In an embodiment of the present invention, the micro-rough layer is disposed between the buffer layer and the first contact layer, or disposed between the first contact layer and the first cladding layer.

In an embodiment of the present invention, the second-type doped semiconductor layer includes a second cladding layer and a second contact layer. The second cladding layer is disposed on the light-emitting layer, while the second contact layer is disposed on the second cladding layer.

In an embodiment of the present invention, the micro-rough layer is between the second cladding layer and the second contact layer.

In an embodiment of the present invention, the micro-rough layer includes a silicon nitride layer or a magnesium nitride layer, wherein the silicon nitride layer or the magnesium nitride layer includes a plurality of randomly distributed mask patterns, respectively.

In an embodiment of the present invention, the micro-rough layer includes a plurality of silicon nitride layers and a plurality of indium gallium nitride (InGaN) layers, wherein the silicon nitride layers and the InGaN layers are stacked on one another. In addition, the micro-rough layer can include a plurality of magnesium nitride layers and a plurality of indium gallium nitride (InGaN) layers as well, wherein the magnesium nitride layers and the InGaN layers are stacked on one another.

In an embodiment of the present invention, the micro-rough layer includes a plurality of silicon nitride layers and a plurality of aluminum indium gallium nitride (AlInGaN) layers, wherein the silicon nitride layers and the AlInGaN layers are stacked on one another. In addition, the micro-rough layer can include a plurality of magnesium nitride layers and a plurality of aluminum indium gallium nitride (AlInGaN) layers as well, wherein the magnesium nitride layers and the AlInGaN layers are stacked on one another.

As embodied and broadly described herein, the present invention provides a LED chip including a substrate, a semiconductor layer, a first electrode and a second electrode and a micro-rough layer. The first electrode and the second electrode are located on the semiconductor layer, wherein the first electrode is electrically insulated from the second electrode. The micro-rough layer is disposed between the semiconductor layer and the substrate, or on an upper surface of the semiconductor layer.

In an embodiment of the present invention, the micro-rough layer includes a silicon nitride layer or a magnesium nitride layer, wherein the silicon nitride layer or the magnesium nitride layer includes a plurality of randomly distributed mask patterns, respectively.

In an embodiment of the present invention, the micro-rough layer includes a plurality of silicon nitride layers and a plurality of indium gallium nitride (InGaN) layers, wherein the silicon nitride layers and the InGaN layers are stacked on one another. In addition, the micro-rough layer can include a plurality of magnesium nitride layers and a plurality of indium gallium nitride (InGaN) layers as well, wherein the magnesium nitride layers and the InGaN layers are stacked on one another.

In an embodiment of the present invention, the micro-rough layer includes a plurality of silicon nitride layers and a plurality of aluminum indium gallium nitride (AlInGaN) layers, wherein the silicon nitride layers and the AlInGaN layers are stacked on one another. In addition, the micro-rough layer can include a plurality of magnesium nitride layers and a plurality of aluminum indium gallium nitride (AlInGaN) layers as well, wherein the magnesium nitride layers and the AlInGaN layers are stacked on one another.

In summary, the micro-rough layer employed in the LED chip of the present invention, is able to reduce the total reflection for photons. Thus, the external quantum efficiency is enhanced and the LED chip accordingly has better luminous efficiency.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1A and FIG. 1B are schematic cross-sectional drawings of two LED chips according to the first embodiment of the present invention.

FIG. 2A and FIG. 2B are local cross-sectional diagrams showing two micro-rough layers, respectively.

FIG. 3 is a partially-enlarged cross-sectional diagram of a LED chip.

FIGS. 4A˜4E are cross-sectional diagrams showing a plurality of LED chips, respectively, according to the present invention.

FIGS. 5A˜5C are cross-sectional diagrams showing a plurality of LED chips, respectively, according to the present invention.

FIG. 6A and FIG. 6B are cross-sectional diagrams showing two LED chips, respectively, according to the second embodiment of the present invention.

FIG. 7 is a comparison chart of brightness vs. injected current between a conventional LED chip and a LED chip of the present invention.

### DESCRIPTION OF THE EMBODIMENTS

The First Embodiment

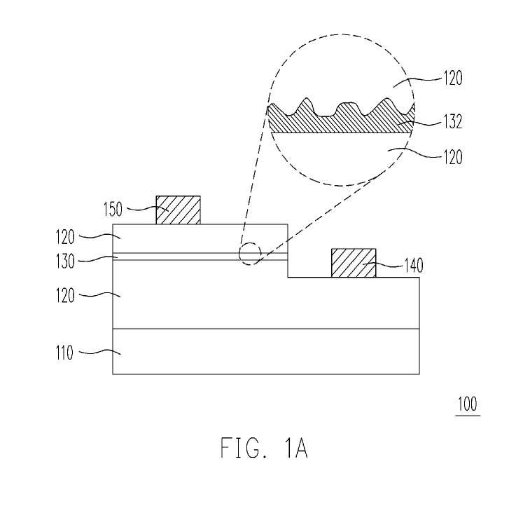

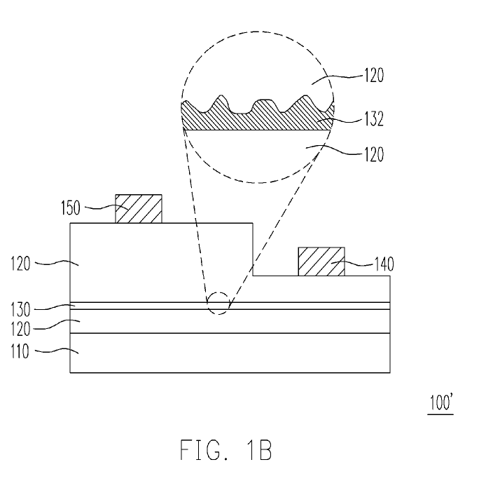

FIGS. 1A and 1B are schematic cross-sectional drawings of two LED chips according to the first embodiment of the present invention. Referring to FIGS. 1A and 1B, each of LED chips 100 and 100′ of the present embodiment includes a substrate 110, a semiconductor layer 120, a micro-rough layer 130, a first electrode 140 and a second electrode 150. The semiconductor layer 120 is disposed on the substrate 110, while the micro-rough layer 130 is disposed in the semiconductor layer 120. The first electrode 140 and the second electrode 150 are disposed on the semiconductor layer 120, wherein the first electrode 140 is electrically insulated from the second electrode 150. As a forward current is applied to the semiconductor layer 120 from the first electrode 140 and the second electrode 150, photons are generated in the semiconductor layer 120. The micro-rough layer 130 serves for reducing the total reflection for photons. Thus, the photons can easily escape from the LED chips 100 or 100′ and the LED chips 100 or 100′ accordingly have better luminous efficiency.

The above-described micro-rough layer 130 comprises, for example, a silicon nitride layer 132 and the surface thereof is roughened. The material of the silicon nitride layer 132 includes silicon nitride (SiₐN_{b}, 0<a,b<1). The preferred thickness of the silicon nitride layer 132 is between 2Å˜50Å and the preferred growth temperature thereof is between 600° C. ˜1100° C. Note that the micro-rough layer 130 in the present invention is not limited to a single silicon nitride layer 132. The other compositions of the micro-rough layer 130 are explained hereinafter with accompanying drawings.

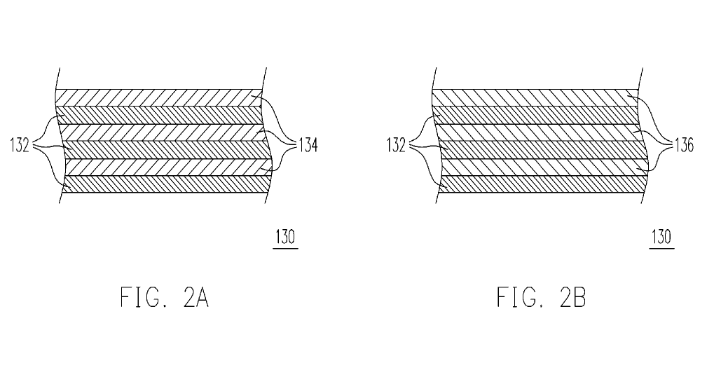

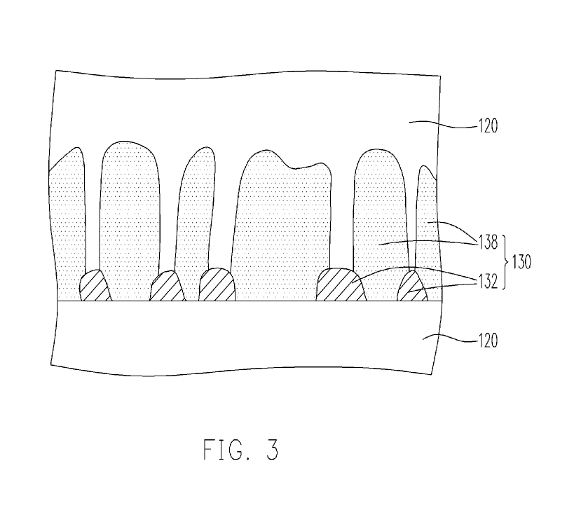

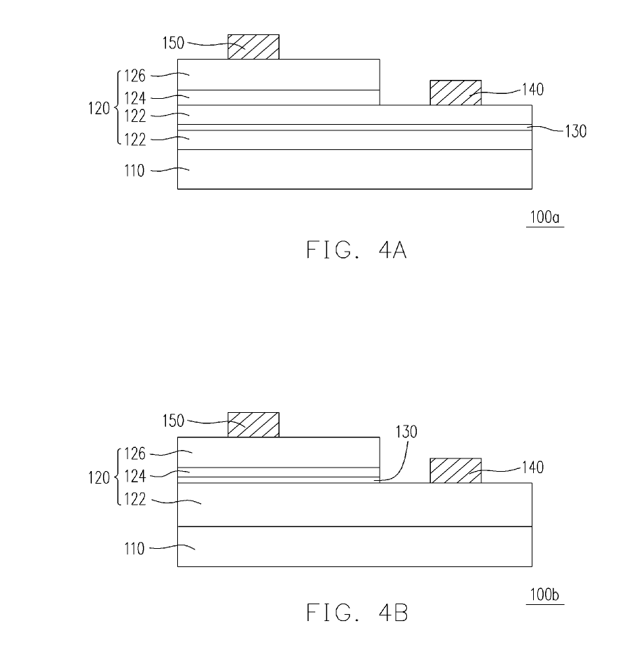

FIGS. 2A and 2B are local cross-sectional diagrams showing two micro-rough layers, respectively. Referring to FIG. 2A, the micro-rough layer 130 is formed by a plurality of silicon nitride layers 132 and a plurality of indium gallium nitride layers 134, wherein the two kinds of layers are stacked on one another in a form of short period super lattice structure. The material of the silicon nitride layer 132 includes silicon nitride (SiₐN_{b}, 0<a,b<1), while the material of the indium gallium nitride layer 134 includes indium gallium nitride (InₕGa₁₋ₕN, 0≦h<1). In addition, the preferred thickness of each silicon nitride layer 132 and each indium gallium nitride layer 134 is between 2Å˜20Å, while the preferred growth temperature thereof is between 600° C.˜1100° C. The compound compositions of each silicon nitride layer 132, namely ‘a’ and ‘b’ in the above-mentioned chemical formula, are not necessarily the same, and the compound compositions of each indium gallium nitride layer 134 (‘h’ in the above-mentioned chemical formula) are not necessarily the same. The preferred overall thickness of the micro-rough layer 130 should not exceed 200Å. Note that the silicon nitride layer 132 can be substituted by a magnesium nitride layer or other similar material layers.

Referring to FIG. 2B, the micro-rough layer 130 is, as mentioned, formed by a plurality of silicon nitride layers 132 and a plurality of aluminum indium gallium nitride layers 136, wherein the two kinds of layers are stacked on one another, in the form of short period and super lattice structure. The material of the silicon nitride layer 132 includes silicon nitride (SiₐN_{b}, 0<a,b<1), while the material of the aluminum indium gallium nitride layers 136 includes aluminum indium gallium nitride (AlₘInₙGa₁₋ₘ₋ₙN, 0≦m,n<1, m+n<1). In addition, the preferred thickness of each silicon nitride layer 132 and each aluminum indium gallium nitride layers 136 is between 2Å˜20Å, while the preferred growth temperature thereof is between 600° C.˜1100° C. The compound compositions of each silicon nitride layer 132, namely ‘a’ and ‘b’ in the above-mentioned molecular formula, are not necessarily the same, and the compound compositions of each aluminum indium gallium nitride layers 136 (‘m’ and ‘n’ in the above-mentioned chemical formula) are not necessarily the same. The preferred overall thickness of the micro-rough layer 130 should not exceed 200Å. Note that the silicon nitride layer 132 can be substituted by a magnesium nitride layer or other similar material layers.

In the above-described embodiments, the micro-rough layer 130 comprises a plurality of thin film layers made of two different materials, respectively and stacked on one another. However, the present invention does not limit the micro-rough layer 130 to be constituted by two different materials, and the materials of the thin film layers are not limited to silicon nitride, magnesium nitride, indium gallium nitride or aluminum indium gallium nitride. In fact, for example, the present invention can use a plurality of thin film layers of over three different materials (such as silicon nitride, magnesium nitride, indium gallium nitride, aluminum indium gallium nitride or others), stacked on one another, to form a micro-rough layer having a structure of short period and super lattice. In addition, the micro-rough layer 130 is not necessarily formed by stacking the thin film layers on one another. In the following, other ways of forming the micro-rough layer 130 are explained with accompanying drawings.

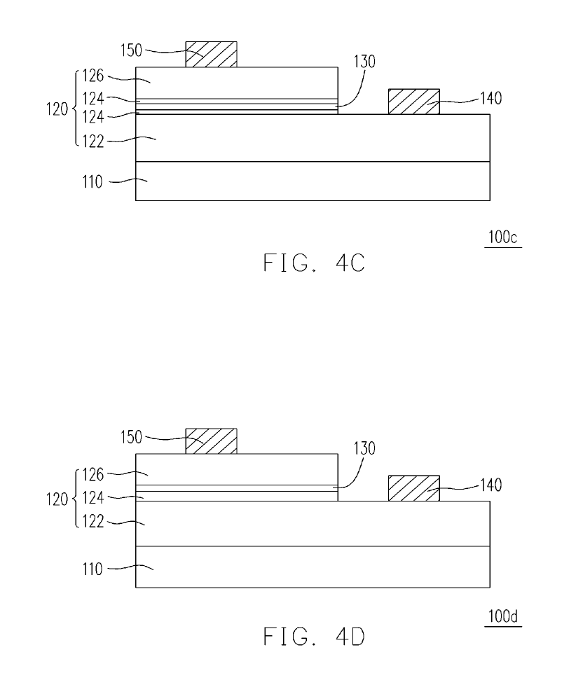

FIG. 3 is a partially-enlarged cross-sectional diagram of a LED chip. Referring to FIG. 3, to form the micro-rough layer 130, a silicon nitride layer 132 is formed on a semiconductor layer 120 first, wherein the silicon nitride layer 132 has a plurality of randomly distributed mask patterns. The material of the silicon nitride layer 132 includes silicon nitride (SiₐN_{b}, 0<a,b<1), also magnesium nitride (Mg_{c}N_{d}, 0<c,d<1) or aluminum indium gallium nitride (AlₛInₜGa₁₋ₛ₋ₜN, 0<s,t<1, s+t<1), wherein silicon and magnesium are high-doped. Besides, the randomly distributed mask patterns of the silicon nitride layer 132 (the same for magnesium nitride or aluminum indium gallium nitride high-doped with silicon and magnesium) are formed, for example, by metal organic chemical vapor deposition (MOCVD). The preferred thickness of each silicon nitride layer 132 is between 5Å˜100Å, while the preferred growth temperature thereof is between 600° C.˜1100° C. Next, a rough-contact layer 138 is formed from the randomly distributed mask patterns up. Wherein, the material of the rough-contact layer 138 includes aluminum indium gallium nitride (AlᵤInᵥGa₁₋ᵤ₋ᵥN, 0<u,v<1, u+v<1), the preferred thickness thereof is between 500Å˜10000Å, while the preferred growth temperature thereof is between 800° C.˜1100° C. The rough-contact layer 138 is not grown directly on the silicon nitride layer 132, but on the upper surfaces of the semiconductor layer 120 uncovered by the silicon nitride layer 132 up until to a certain height beyond the silicon nitride layer 132. After the micro-rough layer 130 is fabricated, the semiconductor layer 120 is continuously formed to complete the entire LED chip.

The detailed structure of the LED chip semiconductor layer and the relative position to the micro-rough layer are explained hereinafter.

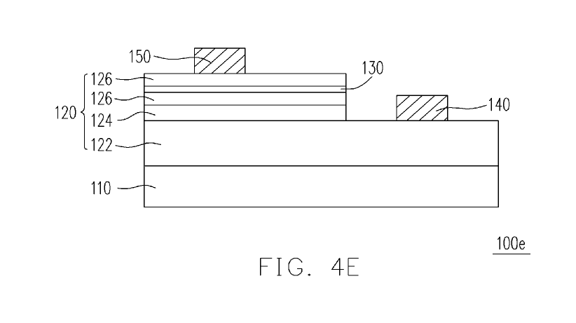

FIGS. 4A˜4E are cross-sectional diagrams showing a plurality of LED chips, respectively, according to the present invention. Referring to FIGS. 4A˜4E, the LED chips 100a, 100b, 100c, 100d and 100e here are similar to the above-described LED chips 100 and 100′ (shown in FIG. 1A and FIG. 1B), except that the semiconductor layers 120 of the LED chips 100a, 100b, 100c, 100d and 100e further include a first-type doped semiconductor layer 122, a light-emitting layer 124 and a second-type doped semiconductor layer 126. The first-type doped semiconductor layer 122 is disposed on the substrate 110, the light-emitting layer 124 is disposed on a portion of the first-type doped semiconductor layer 122, while the second-type doped semiconductor layer 126 is disposed on the light-emitting layer 124. A first electrode 140 is electrically connected to the first-type doped semiconductor layer 122, while a second electrode 150 is electrically connected to the second-type doped semiconductor layer 126.

Furthermore, in FIG. 4A the micro-rough layer 130 resides in the first-type doped semiconductor layer 122; in FIG. 4B the micro-rough layer 130 resides between the first-type doped semiconductor layer 122 and the light-emitting layer 124; in FIG. 4C the micro-rough layer 130 resides in the light-emitting layer 124; in FIG. 4D the micro-rough layer 130 resides between the light-emitting layer 124 and the second-type doped semiconductor layer 126; and in FIG. 4E the micro-rough layer 130 resides in the second-type doped semiconductor layer 126.

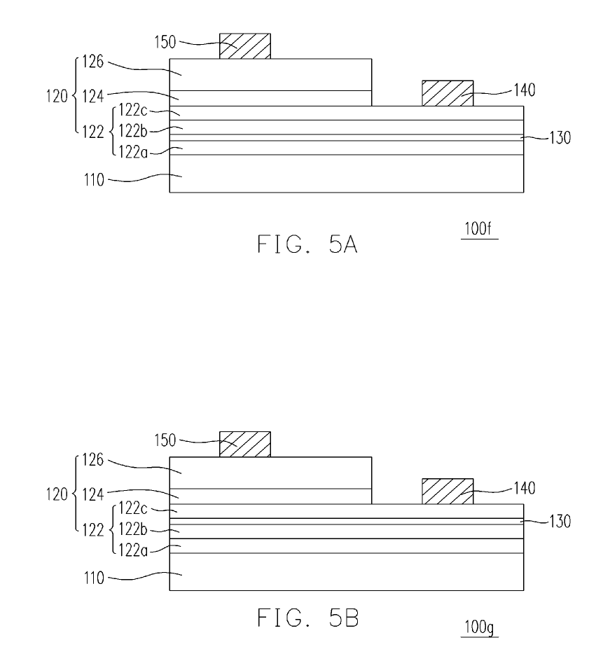

FIGS. 5A˜5C are cross-sectional diagrams showing a plurality of LED chips, respectively, according to the present invention. Referring to FIGS. 5A and 5B, the LED chips 100f and 100g here are similar to the above-described LED chip 100a (shown in FIG. 4A), except that the first-type doped semiconductor layers 122 of the LED chips 100f and 100g further include a buffer layer 122a, a first contact layer 122b and a first cladding layer 122c, respectively. The buffer layer 122a is disposed on the substrate 110, the first contact layer 122b is disposed on the buffer layer 122a, while the first cladding layer 122c is disposed on the first contact layer 122b.

In addition, in FIG. 5A the micro-rough layer 130 resides between the buffer layer 122a and the first contact layer 122b and in FIG. 5B the micro-rough layer 130 resides between the first contact layer 122b and the first cladding layer 122c.

Referring to FIG. 5C, the LED chip 100h here is similar to the above-described LED chip 100e (shown in FIG. 4E), except that the second-type doped semiconductor layer 126 of the LED chip 100h further includes a second cladding layer 126a and a second contact layer 126b. The second cladding layer 126a is disposed on the light-emitting layer 124, while the second contact layer 126b is disposed on the second cladding layer 126a. Besides, the micro-rough layer 130 resides between the second cladding layer 126a and the second contact layer 126b.

In all the above-described LED chips, as a forward current is injected into the semiconductor layer 120 from the first electrode 140 and the second electrode 150, electrons and holes are transmitted into the light-emitting layer 124 through the first-type doped semiconductor layer 122 and the second-type doped semiconductor layer 126 for recombination, then release energy in the form of photons. Since a micro-rough layer 130 is disposed in the semiconductor layer 120, the photons traveling back and fourth within the semiconductor layer 120 due to a total reflection can be reduced, such that the photons can escape from the LED chip more easily.

The substrates, the materials and forms of each thin film layer in the above-described LED chips are explained hereinafter.

The material of the substrate 110 includes sapphire (Al₂O₃), aluminum carbide (6H-SiC, or 4H-SiC), silicon (Si), zinc oxide (ZnO), gallium arsenide (GaAs), spinel (MgAl₂O₄) or other mono-crystal oxides with a lattice constant close to the constant of the nitride semiconductor. The material structure morphology of the substrate 110 is, for example, C-plane, E-plane or A-plane.

The first-type doped semiconductor layer 122 has a different doping type from the second-type doped semiconductor layer 126. In the embodiment, the first-type doped semiconductor layer 122 is, for example, a N-type semiconductor layer, while the second-type doped semiconductor layer 126 correspondingly is a P-type semiconductor layer. Surely, the just-mentioned different doping types for the first-type doped semiconductor layer 122 and the second-type doped semiconductor layer 126 can be switched. In addition, the light-emitting layer 124 can be made of indium gallium nitride (InₐGa₁₋ₐN) and can emit lights with different wavelengths by using different content proportions of indium over gallium.

The above-described buffer layer 122a is made of, for example, aluminum gallium indium nitride (AlₐGa_{b}In_{1-a-b}N, 0≦a,b≦1, a+b<1). The first contact layer 122b can be N-type contact layer and the first cladding layer 122c can be N-type cladding layer. The second contact layer 126b can be P-type contact layer and the second cladding layer 126a can be P-type cladding layer. The N-type contact layer, N-type cladding layer, P-type contact layer and the P-type cladding layer are made of, for example, material of the gallium nitride family, while the characteristics thereof can be adjusted by specifying different dopants and doped ion concentration.

The above-described first electrode 140 is made of, for example, aluminum (Al), platinum (Pt), palladium (Pd), cobalt (Co), molybdenum (Mo), beryllium (Be), gold (Au), titanium (Ti), chromium (Cr), tin (Sn), tantalum (Ta), titanium nitride (TiN), titanium tungsten nitride (TiWNₐ), tunsten silicide (WSiₐ) or other similar materials. The first electrode 140 is formed by a single layer or multiple layers of metal or alloy. The second electrode 150 is made of, for example, nickel (Ni), platinum (Pt), cobalt (Co), palladium (Pd), beryllium (Be), gold (Au), titanium (Ti), chromium (Cr), tin (Sn), tantalum (Ta), titanium nitride (TiN), titanium tungsten nitride (TiWNₐ), tunsten silicide (WSiₐ) or other similar materials. The second electrode 150 is formed by a single layer or multiple layers of metal or alloy.

The Second Embodiment

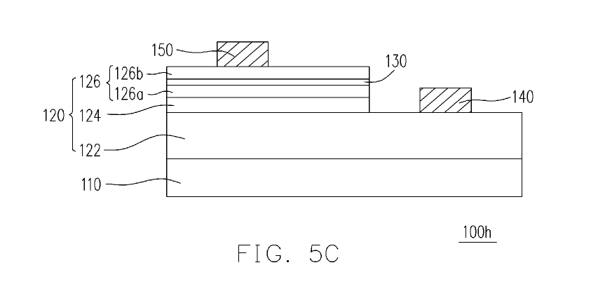

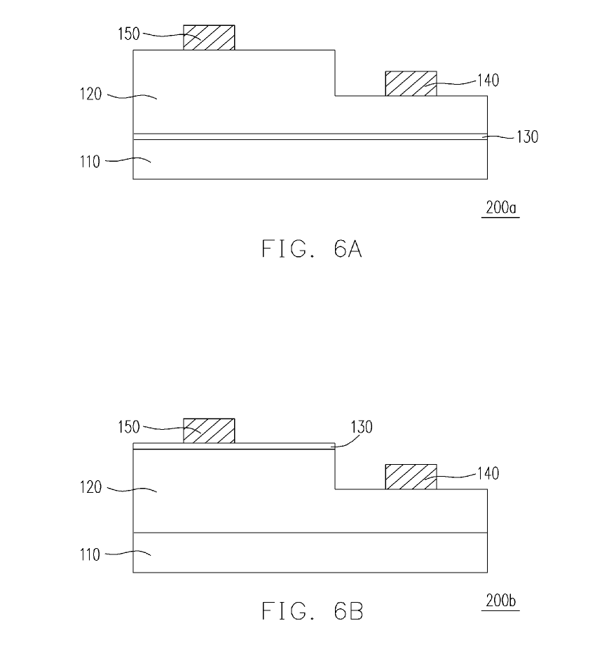

FIG. 6A and FIG. 6B are cross-sectional diagrams showing two LED chips, respectively, according to the second embodiment of the present invention. Referring to FIG. 6A, the LED chips 200a here is similar to the above-described LED chips 100 and 100′ (shown in FIGS. 1A and 1B), except that the micro-rough layer 130 of the LED chip 200a is disposed between the semiconductor layer 120 and the substrate 110. Referring to FIG. 6B, the LED chips 200b here is similar to the above-described LED chips 100 and 100′ (shown in FIGS. 1A and 1B), except that the micro-rough layer 130 of the LED chip 200b is disposed on the upper surface of the semiconductor layer 120.

In the above-described LED chips 200a and 200b, the micro-rough layers 130 are disposed between the semiconductor layer 120 and the substrate 110 and between the semiconductor layer 120 and the air (not shown) outside the upper surface of the semiconductor layer 120, respectively. Therefore, the micro-rough layers 130 can reduce total-reflection on the two interfaces between the semiconductor layer 120 and the substrate 110 and between the semiconductor layer 120 and the outside air, respectively and further enhance the luminous efficiency of the LED chips 200a and 200b. Note that, due to the low band-gap of the micro-rough layers 130 in the LED chip 200b, the resistance between the second electrode 150 and the micro-rough layers 130 is lower than that between the conventional second electrode 150 and the semiconductor layer 120 (without micro-rough layers 130), such that Ohm contact can be formed more easily.

In all the above-described LED chips of the present invention, a transparent conductor layer (not shown) can be further included, wherein the transparent conductor layer is disposed on the semiconductor layer 120 and electrically connected to the second electrode 150. The transparent conductor layer can be a metal conductor layer or a transparent oxide layer. The material of the metal conductor layer is, for example, nickel (Ni), platinum (Pt), cobalt (Co), palladium (Pd), beryllium (Be), gold (Au), titanium (Ti), chromium (Cr), tin (Sn), tantalum (Ta) or other similar materials. The metal conductor layer is formed by a single layer or multiple layers of metal or alloy. The material of the transparent oxide layer is, for example, indium tin oxide (ITO), CTO, ZnO:Al, ZnGa₂O₄, SnO₂:Sb, Ga₂O₃:Sn, AgInO₂:Sn, In₂O₃:Zn, CuAl0₂, LaCuOS, NiO, CuGa0₂ or SrCu₂O₂ and the transparent oxide layer is formed by a single layer or multiple layers of thin films.

The Third Embodiment

In all the above-described LED chips, the micro-rough layers 130 are disposed at different positions in the LED chips, but the present invention does not limit the quantity of the micro-rough layers 130. For example, two micro-rough layers 130 can be simultaneously disposed between the first-type doped semiconductor layer 122 and the light-emitting layer and between the light-emitting layer 124 and the second-type doped semiconductor layer 126, respectively (referring to FIGS. 4B and 4D), so that the photons released from light-emitting layer 124 traveling back and fourth due to a total reflection can be largely reduced. Moreover, the micro-rough layers 130 can be disposed at any available positions in the LED chips. As a result, the LED chips of the present invention can have better luminous efficiency.

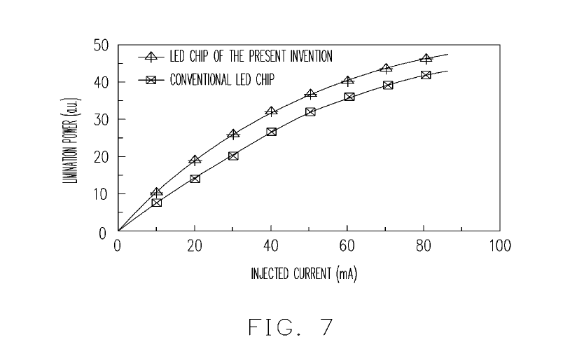

FIG. 7 is a data comparison chart of brightness vs. injected current between a conventional LED chip and a LED chip of the present invention. Wherein, the conventional LED chip does not contain a micro-rough layer, while the LED chip of the present embodiment contains a micro-rough layer, which is formed by a plurality of silicon nitride layers and a plurality of indium gallium nitride layers (In_{0.2}Ga_{0.8}N) stacked on one another and the micro-rough layer has a structure of short period and super lattice. Referring to FIG. 7, obviously the luminous efficiency of the invented LED chip is better than that of the conventional LED chip. In other words, the disposed micro-rough layer is proven to be able to enhance the luminous efficiency of a LED chip.

In summary, in the LED chip of the present invention, with a micro-rough layer, the luminous efficiency of the LED chip is consequently enhanced.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A light-emitting diode chip (LED chip), comprising:
a substrate;
a semiconductor layer, disposed on the substrate;
a micro-rough layer, disposed in the semiconductor layer;
a first electrode, disposed on the semiconductor layer; and
a second electrode, disposed on the semiconductor layer, wherein the first electrode is electrically insulated from the second electrode.

2. The LED chip as recited in claim 1, wherein the semiconductor layer comprises:
a first-type doped semiconductor layer, disposed on the substrate;
a light-emitting layer, disposed on a portion of the first-type doped semiconductor layer; and
a second-type doped semiconductor layer, disposed on the light-emitting layer, wherein the first electrode is electrically connected to the first-type doped semiconductor layer, while the second electrode is electrically connected to the second-type doped semiconductor layer.

3. The LED chip as recited in claim 2, wherein the micro-rough layer is disposed in the first-type doped semiconductor layer.

4. The LED chip as recited in claim 2, wherein the micro-rough layer is disposed between the first-type doped semiconductor layer and the light-emitting layer.

5. The LED chip as recited in claim 2, wherein the micro-rough layer is disposed in the light-emitting layer.

6. The LED chip as recited in claim 2, wherein the micro-rough layer is disposed between the light-emitting layer and the second-type doped semiconductor layer.

7. The LED chip as recited in claim 2, wherein the micro-rough layer is disposed in the second-type doped semiconductor layer.

8. The LED chip as recited in claim 2, wherein the first-type doped semiconductor layer is a N-type semiconductor layer, while the second-type doped semiconductor layer is a P-type semiconductor layer.

9. The LED chip as recited in claim 2, wherein the first-type doped semiconductor layer comprises:
a buffer layer, disposed on the substrate;
a first contact layer, disposed on the buffer layer; and
a first cladding layer, disposed on the first contact layer.

10. The LED chip as recited in claim 9, wherein the micro-rough layer is disposed between the buffer layer and the first contact layer.

11. The LED chip as recited in claim 9, wherein the micro-rough layer is disposed between the first contact layer and the first cladding layer.

12. The LED chip as recited in claim 2, wherein the second-type doped semiconductor layer comprises:
a second cladding layer, disposed on light-emitting layer; and
a second contact layer, disposed on the second cladding layer.

13. The LED chip as recited in claim 12, wherein the micro-rough layer is disposed between the second cladding layer and the second contact layer.

14. The LED chip as recited in claim 1, wherein the micro-rough layer comprises a silicon nitride layer or a magnesium nitride layer.

15. The LED chip as recited in claim 14, wherein the silicon nitride layer or the magnesium nitride layer comprises a plurality of randomly distributed mask patterns.

16. The LED chip as recited in claim 1, wherein the micro-rough layer comprises:
a plurality of silicon nitride layers or magnesium nitride layers; and
a plurality of indium gallium nitride layers, wherein the silicon nitride layers and the indium gallium nitride layers are stacked on one another, or the magnesium nitride layers and the indium gallium nitride layers are stacked on one another.

17. The LED chip as recited in claim 1, wherein the micro-rough layer comprises:
a plurality of silicon nitride layers or magnesium nitride layers; and
a plurality of aluminum indium gallium nitride layers, wherein the silicon nitride layers and the aluminum indium gallium nitride layers are stacked on one another, or the magnesium nitride layers and the aluminum indium gallium nitride layers are stacked on one another.

18. A LED chip, comprising:
a substrate;
a semiconductor layer, disposed on the substrate;
a first electrode, disposed on the semiconductor layer;
a second electrode, disposed on the semiconductor layer, wherein the first electrode is electrically insulated from the second electrode; and
a micro-rough layer, disposed between the semiconductor layer and the substrate or disposed on an upper surface of the semiconductor layer.

19. The LED chip as recited in claim 18, wherein the micro-rough layer comprises a silicon nitride layer or a magnesium nitride layer.

20. The LED chip as recited in claim 19, wherein the silicon nitride layer or the magnesium nitride layer comprises a plurality of randomly distributed mask patterns.

21. The LED chip as recited in claim 18, wherein the micro-rough layer comprises:
a plurality of silicon nitride layers or magnesium nitride layers; and
a plurality of indium gallium nitride layers, wherein the silicon nitride layers and the indium gallium nitride layers are stacked on one another, or the magnesium nitride layers and the indium gallium nitride layers are stacked on one another.

22. The LED chip as recited in claim 18, wherein the micro-rough layer comprises:
a plurality of silicon nitride layers or magnesium nitride layers; and
a plurality of aluminum indium gallium nitride layers, wherein the silicon nitride layers or the magnesium nitride layers and the aluminum indium gallium nitride layers are stacked on one another, or the magnesium nitride layers and the aluminum indium gallium nitride layers are stacked on one another.
